(19) United States
(12) Patent Application Publication
(10) Pub. No.: US 2026/0142623 A1
(43) Pub. Date: May 21, 2026

(54) HIGH PEAKING FREQUENCY DIFFERENTIAL CASCODE TRANSFORMER AMPLIFIER

(71) Applicant: MACOM Technology Solutions Holdings, Inc., Lowell, MA (US)

(72) Inventors: Duy P. Nguyen, San Jose, CA (US); Trong Phan, Garden Grove, CA (US); Nguyen L.K. Nguyen, Bedford, MA (US); William M. Allen, Gansevoort, NY (US)

(21) Appl. No.: 18/950,689

(22) Filed: Nov. 18, 2024

(51) Int. Cl. H03F 1/42; H03F 3/45

(52) U.S. Cl. CPC H03F 1/42; H03F 3/45089; H03F 3/45475

(57) ABSTRACT

Amplifiers with differential transformers for high peaking frequency are described herein. An example amplifier includes a differential transistor pair, an auxiliary transistor pair coupled to the differential transistor pair, a differential transformer coupled between base terminals of the auxiliary transistor pair, and a bias circuit coupled between base terminals of the auxiliary transistor pair. The differential transformer can be embodied as a coupled-line transformer. The bias circuit can include a first bias circuit coupled between a first coupled line of the differential transformer and a base terminal of a first transistor among the auxiliary transistor pair, and a second bias circuit coupled between a second coupled line of the differential transformer and a base terminal of a second transistor among the auxiliary transistor pair.

### BACKGROUND

A range of different amplifiers are known and relied upon for data communications. Differential amplifiers, as an example, are commonly used for high-speed data communications. Differential amplifiers are designed to amplify the difference between two input signals and to reject noise or interference that is present on both (i.e., common to) the input signals. Differential amplifiers are often used in multi-stage amplifiers, and multiple differential amplifier stages can be cascaded depending on design needs and the amplification application. Each amplifier stage can have a different amplifier configuration.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Amplifiers with differential transformers for high peaking frequency are described herein. An example amplifier includes a differential transistor pair, an auxiliary transistor pair coupled to the differential transistor pair, a differential transformer coupled between base terminals of the auxiliary transistor pair, and a bias circuit coupled between base terminals of the auxiliary transistor pair. The differential transformer can be embodied as a coupled-line transformer in one example. The differential transformer can be embodied as an inductive transformer in another example.

In some examples, the differential transformer can include a pair of spaced-apart metal traces that extend parallel to each other for a length and a pair of series-connected capacitors coupled at ends of the metal traces. An AC ground of the amplifier circuit can be positioned between the pair of series-connected capacitors. In other examples, the differential transformer can include an inductive transformer with metal traces that extend in a looped configuration in proximity to each other.

In other aspects, the bias circuit is configured to maintain a DC bias at base terminals of the auxiliary transistor pair using closed loop control based on a reference voltage. The bias circuit can include a first bias circuit coupled between a first coupled line of the differential transformer and a base terminal of a first transistor among the auxiliary transistor pair, and a second bias circuit coupled between a second coupled line of the differential transformer and a base terminal of a second transistor among the auxiliary transistor pair.

In other aspects, the first bias circuit can include a first sink transistor coupled to the base terminal of the first transistor, a voltage reference generator, and a first differential amplifier coupled between the base terminal of the first transistor and the voltage reference generator. The second bias circuit can include a second sink transistor coupled to the base terminal of the second transistor, the voltage reference generator, and a second differential amplifier coupled between the base terminal of the second transistor and the voltage reference generator. The first bias circuit can maintain a DC bias at the base terminal of the first transistor using closed loop control based on a reference voltage generated by the voltage reference generator. The second bias circuit can maintain a DC bias at the base terminal of the second transistor using closed loop control based on the reference voltage generated by the voltage reference generator.

Another example amplifier circuit includes a differential transistor pair, an auxiliary transistor pair coupled to the differential transistor pair, and a differential transformer coupled between base terminals of the auxiliary transistor pair. The differential transformer can be embodied as a coupled-line transformer in one example. The differential transformer can be embodied as an inductive transformer in another example.

In some examples, the differential transformer can include a pair of spaced-apart metal traces that extend parallel to each other for a length and a pair of series-connected capacitors coupled at ends of the metal traces. An AC ground of the amplifier circuit can be positioned between the pair of series-connected capacitors. In other examples, the differential transformer can include an inductive transformer with metal traces that extend in a looped configuration in proximity to each other.

In some cases, the amplifier circuit can also include a bias circuit coupled between base terminals of the auxiliary transistor pair and configured to maintain a DC bias at base terminals of the auxiliary transistor pair using closed loop control based on a reference voltage. The bias circuit can include a first bias circuit coupled between a first coupled line of the differential transformer and a base terminal of a first transistor among the auxiliary transistor pair, and a second bias circuit coupled between a second coupled line of the differential transformer and a base terminal of a second transistor among the auxiliary transistor pair.

In other aspects, the first bias circuit can include a first sink transistor coupled to the base terminal of the first transistor, a voltage reference generator, and a first differential amplifier coupled between the base terminal of the first transistor and the voltage reference generator. The second bias circuit can include a second sink transistor coupled to the base terminal of the second transistor, the voltage reference generator, and a second differential amplifier coupled between the base terminal of the second transistor and the voltage reference generator.

In other aspects, the first bias circuit can maintain a DC bias at the base terminal of the first transistor using closed loop control based on a reference voltage generated by the voltage reference generator. The second bias circuit can maintain a DC bias at the base terminal of the second transistor using closed loop control based on the reference voltage generated by the voltage reference generator.

Another example amplifier circuit includes an emitter-follower transistor pair, a common emitter transistor pair, and a differential transformer coupled between base terminals of the common emitter transistor pair. The differential transformer can include a pair of spaced-apart metal traces that extend parallel to each other for a length and a pair of series-connected capacitors coupled at ends of the metal traces. The amplifier can also include a bias circuit coupled between base terminals of the common emitter transistor pair and configured to maintain a DC bias at base terminals of the common emitter transistor pair using closed loop control based on a reference voltage.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example multi-stage amplifier according to various examples described herein.

FIG. 2 illustrates an example differential cascode output stage amplifier circuit according to various examples described herein.

FIG. 3 illustrates an example high peaking frequency differential transformer output stage amplifier circuit according to various examples described herein.

FIG. 4 illustrates an example layout of the amplifier circuit shown in FIG. 3 according to various examples described herein.

FIG. 5 illustrates an example plot of normalized gain over frequency for the amplifier circuits shown in FIGS. 2 and 3 according to various examples described herein.

### DETAILED DESCRIPTION

Receivers, transmitters, and transceivers for emerging data communication applications rely upon amplifier circuits to transfer data signals at higher speeds. The amplifier circuits are often designed for broadband operation and, in some cases, variable and peaking gain control. Differential amplifiers are commonly used for high-speed data communications. Multiple stages of differential amplifiers can be cascaded or connected in series depending on the design needs of a given amplifier application. It can be important to tailor and optimize the operating criteria and performance of each amplifier stage in a multi-stage amplifier.

Some output stage amplifiers are used as driver circuits, such as driver circuits for optical components. Optical drivers often require relatively high peaking gain and bandwidth to compensate for the system losses in optical modulators, modules, and other optical system components. Designing driver circuits for optical system components with high peaking gain and bandwidth can be challenging and often involves trade-offs with other operating specifications, such as power consumption, linearity, stability, and other specifications. Increasing peaking gain and bandwidth at frequencies greater than about 60 GHz can be particularly challenging due to the limitations of semiconductor technology processes and related concerns. The concepts described herein, including amplifiers with differential transformers for high peaking frequency, can be relied upon to achieve amplifier circuits with greater peaking gain and bandwidth, among other benefits.

Amplifiers with differential transformers for high peaking frequency are described herein. An example amplifier includes a differential transistor pair, an auxiliary transistor pair coupled to the differential transistor pair, a differential transformer coupled between base terminals of the auxiliary transistor pair, and a bias circuit coupled between base terminals of the auxiliary transistor pair. The differential transformer can be embodied as a coupled-line transformer. The bias circuit can include a first bias circuit coupled between a first coupled line of the differential transformer and a base terminal of a first transistor among the auxiliary transistor pair, and a second bias circuit coupled between a second coupled line of the differential transformer and a base terminal of a second transistor among the auxiliary transistor pair.

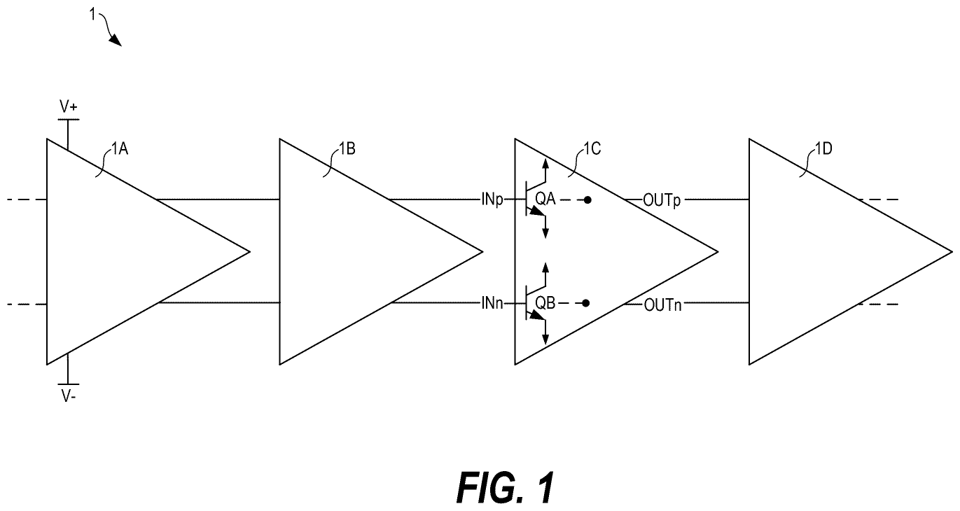

FIG. 1 illustrates an example multi-stage amplifier 1 according to various examples described herein. The multi-stage amplifier 1 can be embodied in various ways, such as using discrete components, as an integrated circuit device formed on a substrate, or as a combination of discrete components and integrated devices. The multi-stage amplifier 1 is depicted as a representative example. The multi-stage amplifier 1 is not exhaustively illustrated in FIG. 1, and the multi-stage amplifier 1 can include additional components that are not shown in some cases. The multi-stage amplifier 1 can also omit certain amplifier stages or components in other cases.

The multi-stage amplifier 1 includes a number of cascaded amplifier circuits or stages, including amplifier stages 1A-1D, among possibly others. In the cascaded configuration shown, the outputs of the amplifier stage 1A are provided as inputs to the amplifier stage 1B. The outputs of the amplifier stage 1B are provided as inputs to the amplifier stage 1C, and so on. Multi-stage amplifiers can be relied upon for increased overall gain, to tailor input or output impedances, and to achieve other objectives for certain data communications applications. Each of the amplifier stages 1A-1D is supplied with power by an upper rail voltage or potential V+ and a lower rail voltage or potential V−.

Each of the amplifier stages 1A-1D can include one or more transistor amplifiers, biasing circuitry, coupling circuitry, and related circuit components. Additionally, the transistor or transistors in each of the amplifier stages 1A-1D can be arranged or configured in different ways (e.g., distributed amplifiers, differential pair amplifiers, Darlington pair amplifiers, common collector or drain amplifiers, common emitter or source amplifiers, common base or gate amplifiers, etc.) depending on the design, objectives, and application for the multi-stage amplifier 1. The amplifier stage 1C is shown to include two transistors QA and QB, as an example, for handling a differential signal. Each of the amplifier stages 1A-1D can be designed, tailored, and optimized independently.

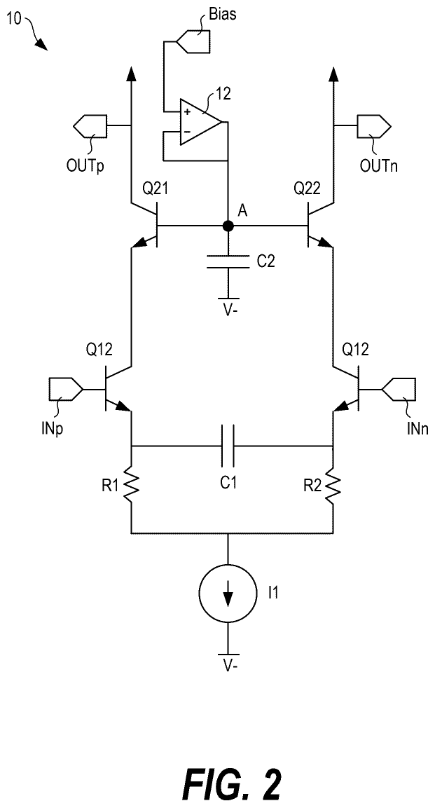

FIG. 2 illustrates an example differential cascode output stage amplifier circuit 10 (also “amplifier 10”) according to various examples described herein. The amplifier circuit 10 can be embodied in various ways, such as using discrete components, as an integrated circuit device formed on a substrate, or as a combination of discrete components and integrated devices. The amplifier circuit 10 is provided as a representative example of an amplifier stage with variable gain control. The amplifier circuit 10 is not exhaustively illustrated in FIG. 2, and the amplifier circuit 10 can include additional components that are not shown. The amplifier circuit 10 can also omit certain components in some cases.

The amplifier circuit 10 shown in FIG. 2 can be used as output amplifier stage for radio frequency (RF) communications, wired communications, optical communications, or for other purposes, without limitation. The gain or operating bias of the amplifier circuit 10 can be varied based on a control input, as described below. The amplifier circuit 10 can be implemented as one of the amplifier stages 1A-1D of the multi-stage amplifier 1 shown in FIG. 1, such as the output amplifier stage 1D. As one example, an input of the amplifier circuit 10 in the multi-stage amplifier 1 can be coupled to an output of the amplifier stage 1C in the multi-stage amplifier 1. The amplifier circuit 10 can also be connected in other ways and to other amplifier stages in a multi-stage amplifier. The amplifier circuit 10 can also be implemented as a stand-alone amplifier circuit, rather than as part of a multi-stage amplifier.

The amplifier circuit 10 includes a differential transistor pair of transistors Q11 and Q12 (also “differential transistors Q11 and Q12”), an auxiliary transistor pair of transistors Q21 and Q22 (also “auxiliary transistors Q21 and Q22”), a current source I1, resistors R1 and R2, capacitors C1 and C2, and a biasing amplifier 12 electrically coupled in the arrangement shown, among possibly other components. The transistor Q21 is arranged or coupled as a common base transistor, and the transistor Q12 is arranged or coupled as a common emitter or emitter-follower transistor. Similarly, transistor Q22 is arranged or coupled as a common base transistor, and the transistor Q22 is arranged or coupled as a common emitter or emitter-follower transistor. Thus, the amplifier circuit 10 comprises a differential cascode amplifier stage and can be relied upon as an output stage of the multi-stage amplifier 1 shown in FIG. 1.

The amplifier circuit 10 is not exhaustively illustrated in FIG. 2, and the amplifier circuit 10 can include additional components that are not shown for biasing, coupling, and other purposes in some cases. As one example, one or more resistors can be coupled between the collector terminals of the main transistors Q21 and Q22 and the upper rail voltage V+. Interstage coupling, blocking, and other capacitors can also be relied upon in some cases as would be understood in the field.

The transistors Q11, Q12, Q21, and Q22 are depicted as bipolar junction transistors in FIG. 2. The transistors can be embodied as field effect transistors (FETs) or other types of transistors in other cases, however, and the concepts described herein are not limited to use with amplifiers or transistors of any particular type or technology. Thus, references to the “base” or “base terminal” of a transistor include a reference to the “gate” or “gate terminal” of a FET transistor. Similarly, references to the “emitter” or “emitter terminal” of a transistor include a reference to the “source” or “source terminal” of a FET transistor, and references to the “collector” or “collector terminal” of a transistor include a reference to the “drain” or “drain terminal” of a FET transistor. Other types and configurations of amplifiers and amplifier circuits can also incorporate the amplifier gain shaping and control concepts described herein.

A differential input INp and INn can be provided to the base terminals of the differential transistors Q11 and Q12 of the amplifier circuit 10. A differential output OUTp and OUTn from the amplifier circuit 10 can be taken from the collector terminals of the auxiliary transistors Q21 and Q22. Although not shown in FIG. 2, the collector terminals of the auxiliary transistors Q21 and Q22 can be coupled to an upper rail voltage or potential V+, possibly through resistors or other circuit components.

The emitter terminals of the differential transistors Q11 and Q12 are coupled together through the capacitor C1 and are coupled to the current source I1 through the resistors R1 and R2. The current source I1 is coupled between the emitter terminals of the differential transistors Q11 and Q12 and a lower rail voltage or potential V− or, in some cases, ground. The base terminals of the differential transistors Q11 and Q12 are coupled to the differential input INp and INn.

The emitter terminals of the auxiliary transistors Q21 and Q22 are coupled to the collectors of the differential transistors Q11 and Q12, respectively. The base terminals of the auxiliary transistors Q21 and Q22 are coupled to each other, and the auxiliary transistors Q21 and Q22 can be referred to as a base-connected auxiliary transistor pair. The node “A” between the base terminals of the auxiliary transistors Q21 and Q22 is an AC or virtual ground in the amplifier circuit 10, and the capacitor C2 is coupled between the node “A” and the lower rail voltage or potential V− or, in some cases, ground. The collector terminals of the auxiliary transistors Q21 and Q22 can be coupled to the upper rail voltage or potential V+, possibly through resistors or other circuit components.

The biasing amplifier 12 is configured to generate a bias potential at the node “A” of the amplifier circuit 10. The biasing amplifier 12 can be embodied as a differential amplifier in the example shown, and other biasing circuits can be relied upon in place of the biasing amplifier 12. A bias control signal is provided to a non-inverting input of the biasing amplifier 12. The biasing amplifier 12 is configured for unity gain, with the output of the biasing amplifier 12 being provided to the inverting input of the biasing amplifier 12. A resistor can also be placed between the output and the inverting input of the biasing amplifier 12 in some cases. The bias control signal can be provided from a gain controller, a voltage reference generator, or another control circuit, which can be implemented as a separate, and possibly external, control device in some cases.

The current source I1 is representative in FIG. 2 and can be implemented as any suitable type of current source or related biasing circuitry for the differential transistors Q11 and Q12 and the amplifier circuit 10. Examples of the current source I1 include transistor-based current mirrors, current regulators, resistors, and combinations thereof, and the current source I1 is not limited to any particular type of current source. The current source I1 can also be implemented as a variable current source in some cases.

The upper rail voltage V+ can be any suitable voltage. In some cases, the circuit ground can be embodied as a lower rail voltage V−, which can also be any suitable voltage or potential that is less than the upper rail voltage V+. The voltages V+ and V− can be selected, respectively, based on the target biasing voltage or voltage range for the amplifier circuit 10. The difference in potential between the upper rail voltage V+ and the lower rail voltage V− or ground can be any suitable potential difference based on the target biasing voltage or voltage range for the amplifier circuit 10.

The amplifier circuit 10 can be biased for operation at a nominal gain and also a variable gain based on the bias potential provided at the node “A” of the amplifier circuit 10.. In that sense, the amplifier circuit 10 can be designed to have the appropriate potentials at the terminals of the transistors Q11, Q12, Q21, and Q22 for operation at nominal and variable gain. Beyond biasing for nominal gain, the gain of the amplifier circuit 10 can be adjusted based on the bias potential provided at the node “A” from the biasing amplifier 12.

The amplifier circuit 10 shown in FIG. 2 can be unsuitable for use as a driver circuit for modern optical components used in emerging data communication applications. However, designing driver circuits for optical system components with high peaking gain and bandwidth can be challenging and often involves trade-offs with other operating specifications, such as power consumption, linearity, stability, and other specifications. Increasing peaking gain and bandwidth at frequencies greater than about 60 GHz can be particularly challenging due to the limitations of semiconductor technology processes and related concerns. The concepts described herein, including the amplifiers with differential transformers for high peaking frequency described below, can be relied upon to achieve amplifier circuits with greater peaking gain and bandwidth, among other benefits.

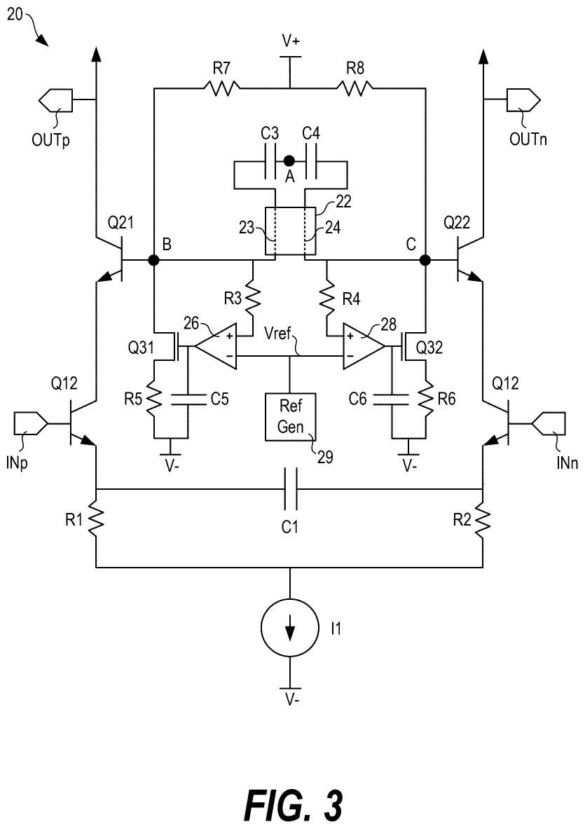

FIG. 3 illustrates an example high peaking frequency differential transformer output stage amplifier circuit 20 (also “amplifier circuit 20”) according to various examples described herein. The amplifier circuit 20 can be embodied in various ways, such as using discrete components, as an integrated circuit device formed on a substrate, or as a combination of discrete components and integrated devices. The amplifier circuit 20 is provided as a representative example of an amplifier stage including a bias circuit and a differential transformer. The amplifier circuit 20 is not exhaustively illustrated in FIG. 3, and the amplifier circuit 20 can include additional components that are not shown. The amplifier circuit 20 can also omit certain components in some cases.

The amplifier circuit 20 can be used for RF communications, wired communications, optical communications, or for other purposes, without limitation. The gain or operating bias of the amplifier circuit 20 can be varied based on a control input, as described below. The amplifier circuit 20 can be implemented as one of the amplifier stages 1A-1D of the multi-stage amplifier 1 shown in FIG. 1, such as the output amplifier stage 1D. As one example, an input of the amplifier circuit 20 in the multi-stage amplifier 1 can be coupled to an output of the amplifier stage 1C in the multi-stage amplifier 1. The amplifier circuit 20 can also be connected in other ways and to other amplifier stages in a multi-stage amplifier. The amplifier circuit 20 can also be implemented as a stand-alone amplifier circuit, rather than as part of a multi-stage amplifier.

The amplifier circuit 20 includes a differential transistor pair of transistors Q11 and Q12 (also “differential transistors Q11 and Q12”), an auxiliary transistor pair of transistors Q21 and Q22 (also “auxiliary transistors Q21 and Q22”), a current source I1, resistors R1 and R2, and a capacitor C1 electrically coupled in the arrangement shown, among possibly other components. The amplifier circuit 20 also includes a bias circuit coupled between base terminals of the auxiliary transistors Q21 and Q22 and a differential transformer 22 coupled between the base terminals of the auxiliary transistors Q21 and Q22. The bias circuit includes resistors R3-R5, operational amplifiers 26 and 28, sink transistors Q31 and Q32, capacitors C5 and C6, and resistors R7 and R8 electrically coupled in the arrangement shown, among possibly other components. A voltage reference generator 29 is coupled to the bias circuit.

The differential transformer 22 includes a pair of inductors or coupled transmission lines 23 and 24 and a pair of series-connected capacitors C3 and C4 in the example shown. In operation, only RF or AC current (and not DC current) flows through the differential transformer 22, and the bias circuit operates to set the DC bias at the base terminals of the auxiliary transistors Q21 and Q22, while bypassing rejecting RF or AC components. These and other aspects of the bias circuit and the differential transformer 22 are described below.

The transistor Q21 is arranged or coupled as a common base transistor, and the transistor Q12 is arranged or coupled as a common emitter transistor. Similarly, transistor Q22 is arranged or coupled as a common base transistor, and the transistor Q22 is arranged or coupled as a common emitter transistor. Thus, the amplifier circuit 20 comprises a differential cascode amplifier stage and can be relied upon as an output stage of the multi-stage amplifier 1 shown in FIG. 1.

The amplifier circuit 20 is not exhaustively illustrated in FIG. 2, and the amplifier circuit 20 can include additional components that are not shown for biasing, coupling, and other purposes in some cases. As one example, one or more resistors can be coupled between the collector terminals of the main transistors Q21 and Q22 and the upper rail voltage V+. Interstage coupling, blocking, and other capacitors can also be relied upon in some cases as would be understood in the field.

The transistors Q11, Q12, Q21, and Q22 are depicted as bipolar junction transistors in FIG. 2. The transistors can be embodied as field effect transistors (FETs) or other types of transistors in other cases, however, and the concepts described herein are not limited to use with amplifiers or transistors of any particular type or technology. Thus, references to the “base” or “base terminal” of a transistor include a reference to the “gate” or “gate terminal” of a FET transistor. Similarly, references to the “emitter” or “emitter terminal” of a transistor include a reference to the “source” or “source terminal” of a FET transistor, and references to the “collector” or “collector terminal” of a transistor include a reference to the “drain” or “drain terminal” of a FET transistor. Other types and configurations of amplifiers and amplifier circuits can also incorporate the amplifier gain shaping and control concepts described herein.

A differential input INp and INn can be provided to the base terminals of the differential transistors Q11 and Q12 of the amplifier circuit 20. A differential output OUTp and OUTn from the amplifier circuit 20 can be taken from the collector terminals of the auxiliary transistors Q21 and Q22. Although not shown in FIG. 3, the collector terminals of the auxiliary transistors Q21 and Q22 can be coupled to an upper rail voltage or potential V+, possibly through resistors or other circuit components.

The emitter terminals of the differential transistors Q11 and Q12 are coupled together through the capacitor C1 and are coupled to the current source I1 through the resistors R1 and R2. The current source I1 is coupled between the emitter terminals of the differential transistors Q11 and Q12 and a lower rail voltage or potential V− or, in some cases, ground. The base terminals of the differential transistors Q11 and Q12 are coupled to the differential input INp and INn.

The emitter terminals of the auxiliary transistors Q21 and Q22 are coupled to the collectors of the differential transistors Q11 and Q12, respectively. The base terminals of the auxiliary transistors Q21 and Q22 are coupled to the bias circuit. The node “A” between the capacitors C3 and C4 is an AC or virtual ground in the amplifier circuit 20. The collector terminals of the auxiliary transistors Q21 and Q22 can be coupled to the upper rail voltage or potential V+, possibly through resistors or other circuit components.

The bias circuit includes the resistors R3-R5, the operational amplifiers 26 and 28, the sink transistors Q31 and Q32, the capacitors C5 and C6, and the resistors R7 and R8. The bias circuit is illustrated as a representative example in FIG. 3, and the bias circuit can vary as compared to that shown. The bias circuit can include additional components or omit one or more of the components shown in some cases. As compared to the amplifier circuit 10 shown in FIG. 2, the bias circuit in the amplifier circuit 20 shown in FIG. 3 replaces the capacitor C2 and the biasing amplifier 12. The bias circuit in the amplifier circuit 20 facilitates higher peaking gain and bandwidth for the amplifier circuit 20, among other benefits.

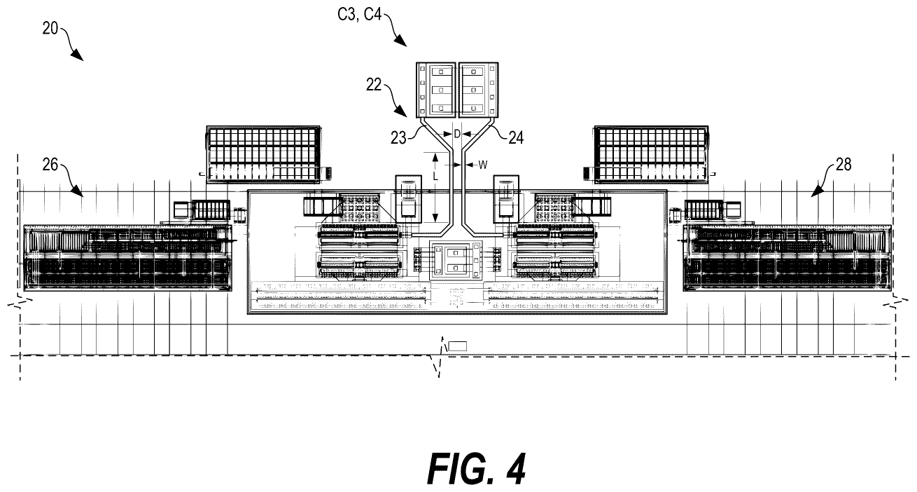

The differential transformer 22 is coupled between the base terminals of the auxiliary transistors Q21 and Q22. The differential transformer 22 can be embodied as a pair of inductors or coupled transmission lines 23 and 24, as one example, that extend in proximity to each other along a length or distance of the coupled transmission lines 21 and 22, as described in further detail below with reference to FIG. 4. The differential transformer 22 can also be embodied as an inductive transformer in other examples. The pair of series-connected capacitors C3 and C4 is coupled at the ends of the transmission lines 23 and 24.

The bias circuit also includes a first bias circuit coupled between the coupled line 23 of the differential transformer 22 and the base terminal of the transistor Q21, and a second bias circuit coupled between the coupled line 23 of the differential transformer 22 and the base terminal of the transistor Q22. The first bias circuit includes the resistor R3, which is coupled to the coupled line 23 and the base terminal of the transistor Q21 at one end and to a non-inverting input of the operational amplifier 26 at another end. The first bias circuit also includes the sink transistor Q31. A drain terminal of the sink transistor Q31 is coupled to the base terminal of the transistor Q21, and a source terminal of the sink transistor Q31 is coupled to the lower rail voltage or potential V− or, in some cases, ground through the resistor R5. The output of the operational amplifier 26 is coupled to a gate terminal of the sink transistor Q31. The capacitor C5 is coupled between the gate terminal of the sink transistor Q31 and the lower rail voltage or potential V− or, in some cases, ground. The voltage reference generator 29 is coupled to an inverting input of the operational amplifier 26.

The second bias circuit includes the resistor R4, which is coupled to the coupled line 24 and the base terminal of the transistor Q22 at one end and to a non-inverting input of the operational amplifier 28 at another end. The second bias circuit also includes the sink transistor Q32. A drain terminal of the sink transistor Q32 is coupled to the base terminal of the transistor Q22, and a source terminal of the sink transistor Q32 is coupled to the lower rail voltage or potential V-or, in some cases, ground through the resistor R6. The output of the operational amplifier 28 is coupled to a gate terminal of the sink transistor Q32. The capacitor C6 is coupled between the gate terminal of the sink transistor Q32 and the lower rail voltage or potential V− or, in some cases, ground. The voltage reference generator 29 is coupled to an inverting input of the operational amplifier 26.

In operation, the bias circuit operates to maintain the DC bias voltages at the base terminals of the auxiliary transistors Q21 and Q22 to be the same as the reference voltage Vref generated by the voltage reference generator 29. The voltage reference generator 29 can be embodied using current mirrors, resistances, and other circuit components capable of generating the reference voltage Vref with suitable precision, preferably over different operating voltages, temperature ranges, etc. of the amplifier circuit 20 during operation. In some cases, the voltage reference generator 29 can be programmable or controllable, to generate one or more different reference voltages over time, or a range of reference voltages over time. Based on the operation of bias circuit, the DC bias voltages at the base terminals of the auxiliary transistors Q21 and Q22 will track the reference voltage Vref.

The potential at the node “B” at the base terminal of the auxiliary transistor Q21 is provided as a non-inverting input to the operational amplifier 26 through the resistor R3. The reference voltage Vref is provided as an inverting input to the operational amplifier 26. The operational amplifier 26 provides a difference voltage output based on any potential difference between the potential at the node “B” at the base terminal of the auxiliary transistor Q21 and the potential of the reference voltage Vref. The difference voltage output from the operational amplifier 26 is provided at the gate terminal of the sink transistor Q31, and the capacitor C5 provides an AC short or filter for any AC component on the difference voltage output from the operational amplifier 26. Based on the control loop provided by the operational amplifier 26, the sink transistor Q31 operates to set the potential at the node “B” to be the same as the reference voltage Vref, by sinking sufficient current through the resistor R7. The resistance of the resistor R7 can be selected to provide a suitable voltage drop between the upper rail voltage or potential V+ and the node “B”, without significant power dissipation. The resistance of the resistor R5 can also be selected to balance the potential at the node “B” across the sink transistor Q31.

The potential at the node “C” at the base terminal of the auxiliary transistor Q22 is provided as a non-inverting input to the operational amplifier 28 through the resistor R4. The reference voltage Vref is provided as an inverting input to the operational amplifier 28. The operational amplifier 28 provides a difference voltage output based on any potential difference between the potential at the node “C” at the base terminal of the auxiliary transistor Q22 and the potential of the reference voltage Vref. The difference voltage output from the operational amplifier 28 is provided at the gate terminal of the sink transistor Q32, and the capacitor C6 provides an AC short or filter for any AC component on the difference voltage output from the operational amplifier 28. Based on the control loop provided by the operational amplifier 28, the sink transistor Q32 operates to set the potential at the node “C” to be the same as the reference voltage Vref, by sinking sufficient current through the resistor R8. The resistance of the resistor R8 can be selected to provide a suitable voltage drop between the upper rail voltage or potential V+ and the node “C”, without significant power dissipation. The resistance of the resistor R6 can also be selected to balance the potential at the node “C” across the sink transistor Q32.

FIG. 4 illustrates an example layout of the amplifier circuit 20 shown in FIG. 3 according to various examples described herein. The coupled transmission lines 23 and 24 of the differential transformer 22, capacitors C3 and C4, and operational amplifiers 26 and 28 are referenced in FIG. 4, among other circuit components of the amplifier circuit 20. The differential transformer 22 can be embodied as a pair of inductors or coupled transmission lines 23 and 24, as one example, that extend in proximity to each other along a length “L” of the coupled transmission lines 21 and 22. The coupled transmission lines 21 and 22 can be embodied as a pair of spaced-apart parallel-extending metal traces, each having a length “L” and a width “W,” as described below. The transmission lines 23 and 24 can also be referred to as a coupled-line transformer. The differential transformer 22 can also be embodied as an inductive transformer, including metal traces that extend in a looped configuration in proximity to each other in another examples.

The coupled transmission lines 23 and 24 each have a length “L” and a width “W” and are separated from each other by a spaced-apart distance “D”. The peaking gain, operating bandwidth, and other operating specifications of the amplifier circuit 20 can be tailored, at least in part, based on the “L,” “W”, and “D” dimensions of the coupled transmission lines 23 and 24. The “L,” “W”, and “D” dimensions of the coupled transmission lines 23 and 24 determines the coupling factor of the differential transformer 22, and the coupling factor can be higher during higher frequency operation of the amplifier circuit 20.

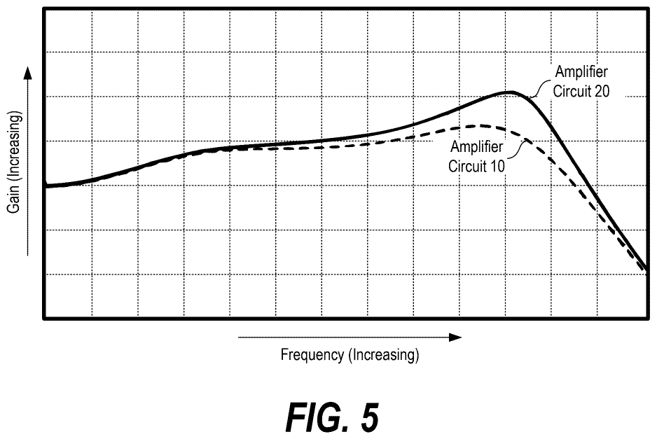

FIG. 5 illustrates an example plot of normalized gain over frequency for the amplifier circuits 10 and 20 shown in FIGS. 2 and 3. At the higher, peaking frequencies of the amplifier circuit 20, the gain curve of the amplifier circuit 20 exhibits more gain than the gain curve of the amplifier circuit 10. Additionally, the gain curve of the amplifier circuit 20 exhibits more gain at higher operating frequencies than the gain curve of the amplifier circuit 10. Thus, the amplifier circuit 20 is capable of both greater peaking gain and greater peaking gain at higher operating frequencies than the amplifier circuit 10, and the amplifier circuit 20 has a larger operating bandwidth than the amplifier circuit 10.

Amplifier circuits including the differential transformers and bias circuits concepts described herein offer a number of benefits, such as increased peaking gain, increased peaking frequency and enhanced system bandwidth. The differential transformers and bias circuits concepts can also be implemented without or without significant power consumption, without or without significant change in amplifier linearity, small changes in amplifier stability, while maintaining unconditional amplifier stability across the full operating bandwidth, and simple layout implementation for a range of semiconductor processes.

The transistors described herein, including the transistors Q11, Q12, Q21, and Q22 can be implemented as a range of different types of transistors formed in a range of different semiconductor materials. The transistors can be formed as bipolar junction transistors, FETs, variants thereof, and other types of transistors, and the concepts can be applied to a range of transistor types. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates. The transistors can be implemented in silicon germanium (SiGe), gallium arsenide (GaAs), gallium nitride (GaN), GaN materials, and other semiconductor materials on or over a range of different substrates. As non-limiting examples, the transistors can be structured as enhancement or depletion mode FET transistors, such as a depletion mode GaAs pHEMT transistors, as GaN HEMT transistors, as GaN materials HEMT transistors, or as related power transistors.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. An amplifier circuit comprising:
a differential transistor pair;
an auxiliary transistor pair coupled to the differential transistor pair;
a differential transformer coupled between base terminals of the auxiliary transistor pair; and
a bias circuit coupled between base terminals of the auxiliary transistor pair.

2. The amplifier circuit according to claim 1, wherein the differential transformer comprises a coupled-line transformer.

3. The amplifier circuit according to claim 1, wherein the differential transformer comprises a pair of spaced-apart metal traces that extend parallel to each other for a length and a pair of series-connected capacitors coupled at ends of the metal traces.

4. The amplifier circuit according to claim 3, further comprising an AC ground of the amplifier circuit between the pair of series-connected capacitors.

5. The amplifier circuit according to claim 1, wherein the differential transformer comprises an inductive transformer.

6. The amplifier circuit according to claim 1, wherein the bias circuit is configured to maintain a DC bias at base terminals of the auxiliary transistor pair using closed loop control based on a reference voltage.

7. The amplifier circuit according to claim 1, wherein the bias circuit comprises:
a first bias circuit coupled between a first coupled line of the differential transformer and a base terminal of a first transistor among the auxiliary transistor pair; and
a second bias circuit coupled between a second coupled line of the differential transformer and a base terminal of a second transistor among the auxiliary transistor pair.

8. The amplifier circuit according to claim 7, wherein:
the first bias circuit comprises a first sink transistor coupled to the base terminal of the first transistor, a voltage reference generator, and a first differential amplifier coupled between the base terminal of the first transistor and the voltage reference generator; and
the second bias circuit comprises a second sink transistor coupled to the base terminal of the second transistor, the voltage reference generator, and a second differential amplifier coupled between the base terminal of the second transistor and the voltage reference generator.

9. The amplifier circuit according to claim 8, wherein:
the first bias circuit maintain a DC bias at the base terminal of the first transistor using closed loop control based on a reference voltage generated by the voltage reference generator; and
the second bias circuit maintain a DC bias at the base terminal of the second transistor using closed loop control based on the reference voltage generated by the voltage reference generator.

10. An amplifier circuit comprising:
a differential transistor pair;
an auxiliary transistor pair coupled to the differential transistor pair; and
a differential transformer coupled between base terminals of the auxiliary transistor pair.

11. The amplifier circuit according to claim 10, wherein the differential transformer comprises a coupled-line transformer.

12. The amplifier circuit according to claim 10, wherein the differential transformer comprises a pair of spaced-apart metal traces that extend parallel to each other for a length and a pair of series-connected capacitors coupled at ends of the metal traces.

13. The amplifier circuit according to claim 10, wherein the differential transformer comprises an inductive transformer.

14. The amplifier circuit according to claim 10, further comprising a bias circuit coupled between base terminals of the auxiliary transistor pair and configured to maintain a DC bias at base terminals of the auxiliary transistor pair using closed loop control based on a reference voltage.

15. The amplifier circuit according to claim 14, wherein the bias circuit comprises:
a first bias circuit coupled between a first coupled line of the differential transformer and a base terminal of a first transistor among the auxiliary transistor pair; and
a second bias circuit coupled between a second coupled line of the differential transformer and a base terminal of a second transistor among the auxiliary transistor pair.

16. The amplifier circuit according to claim 15, wherein:
the first bias circuit comprises a first sink transistor coupled to the base terminal of the first transistor, a voltage reference generator, and a first differential amplifier coupled between the base terminal of the first transistor and the voltage reference generator; and
the second bias circuit comprises a second sink transistor coupled to the base terminal of the second transistor, the voltage reference generator, and a second differential amplifier coupled between the base terminal of the second transistor and the voltage reference generator.

17. The amplifier circuit according to claim 16, wherein:
the first bias circuit maintain a DC bias at the base terminal of the first transistor using closed loop control based on a reference voltage generated by the voltage reference generator; and
the second bias circuit maintain a DC bias at the base terminal of the second transistor using closed loop control based on the reference voltage generated by the voltage reference generator.

18. An amplifier circuit comprising:
an emitter-follower transistor pair;
a common emitter transistor pair; and
a differential transformer coupled between base terminals of the common emitter transistor pair.

19. The amplifier circuit according to claim 10, wherein the differential transformer comprises a pair of spaced-apart metal traces that extend parallel to each other for a length and a pair of series-connected capacitors coupled at ends of the metal traces.

20. The amplifier circuit according to claim 10, further comprising a bias circuit coupled between base terminals of the common emitter transistor pair and configured to maintain a DC bias at base terminals of the common emitter transistor pair using closed loop control based on a reference voltage.
